(19) United States
(12) Patent Application Publication
(10) Pub. No.: US 2006/0063280 A1
(43) Pub. Date: Mar. 23, 2006

(54) Lamp heating apparatus and method for producing semiconductor device

(75) Inventor: Yoshihiro Sohtome, Nara-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaks (JP)

(21) Appl. No.: 11/228,459

(22) Filed: Sep. 19, 2005

(30) Foreign Application Priority Data
Sep. 21, 2004 (JP) 2004-273548

(51) Int. Cl. B08B 6/00; H01L 21/00; B01J 3/04; C23F 1/00

(52) U.S. Cl. 438/5; 432/120; 134/1.2

(57) ABSTRACT

A lamp heating apparatus has: a chamber having a transparent window and housing a substrate; a heating lamp for heating the substrate by radiant heat of a heating lamp through the transparent window; a radiation thermometer that optically detects the temperature of the substrate and has a sensing portion provided in the chamber; a radical generating portion for generating a radical outside the chamber and supplying the radical into the chamber; and a light quantity sensor for determining the time for cleaning the inside of the chamber from a cloudy state of the transparent window and the surface of the sensing portion. This lamp heating apparatus enables a series of operations including heat annealing of the substrate and cleaning of the inside of the chamber. According to this invention, a lamp heating apparatus that has good temperature uniformity and reproductivity of heat processing conditions is obtained.

This non-provisional application claims priority under 35 U.S.C. §119(a) on Japanese Patent Application No. 2004-273548 filed in Japan on September 21, the entire contents of which are hereby incorporated by reference.

### BACKGROUND OF THE INVENTION

1) Field of the Invention

The present invention generally relates to lamp heating apparatuses, and more particularly to a lamp heating apparatuses for rapidly heating the substrate when producing a semiconductor device. The present invention also relates to a method for producing a semiconductor device by using the lamp heating apparatuses.

2) Description of the Related Art

For heat processing that is used in producing semiconductor devices represented by memories and logics, roughly speaking, furnaces and RTA (rapid thermal annealing) are used. In particular, in recent years, miniaturization and thinning of the devices is being promoted very rapidly, and accordingly creating a need for a reduction in the thermal history (thermal budget) of the substrate. To meet this need, RTA processing, which carries out rapid heating and rapid cooling of the substrate, is often used.

General RTA processing is such a method that the substrate is rapidly heated by high heat outputted from a heating lamp, and when the substrate reaches a predetermined temperature, the heating is rapidly discontinued to rapidly cool the substrate. As an apparatus for realizing such an RTA process, a lamp heating apparatus with a heating lamp such as a halogen lamp provided above a susceptor that supports the substrate and with a chamber that has a temperature sensor for detecting the substrate temperature by a non-contact system of, for example, optical system is effective.

In the case where the RTA process is carried out by using the above lamp heating apparatus, a substrate of, for example, Si wafer is mounted on a support by an automatic carry-in/out mechanism, and thereafter a process gas of nitrogen, oxygen, or the like is supplied into a chamber. Next, while carrying out feedback of the substrate temperature by a temperature sensor, the substrate is rapidly heated to a predetermined temperature. In the case where an optical sensor is used as the temperature sensor, for example, a light receiving portion for receiving radiant light that is generated from the rear side of the substrate is provided inside the chamber, and the obtained light is detected, through an optical fiber, by the optical sensor provided outside the chamber. Then, after the substrate reaches a predetermined temperature, this temperature is held for a desired period of time for annealing. The heating lamp is finally turned off to rapidly cool the substrate, and when the substrate is cooled to a predetermined temperature, the substrate is automatically carried out of the chamber.

In conventional heat processing, there has been such a tendency that substances on and inside the substrate diffuse outside the substrate when heated, and the diffusing substances adhere to the inner walls of the chamber, to parts mounted inside the chamber, and further, to the sensing portion of the temperature sensor, to the measuring terminal portion thereof, and the like. In particular, if diffusing substances such as P, As, and B attach to and accumulate on the temperature sensor, and the sensing portion becomes cloudy, stability in temperature measuring and temperature control is undermined, thus making temperature uniformity throughout the wafer plane and temperature reproductivity for each processing impossible. In addition, there is a time when these attached/accumulated substances sublime at the time of heat processing and become incorporated into the substrate. This causes a change in device performance, making it impossible to obtain products as designed.

In particular, in recent years, shallowness (shallow junction) is being promoted, and to also realize low resistance, it is becoming very important in forming miniaturized transistors to heat wafers in which impurities of high density are injected in the extreme surface at a high temperature (e.g., 1000° C.) and for a short period of time (e.g., 1 second or less). Thus, there is an increasing risk of the above-described cloud. As for polysilicon used for wirings, with the promotion of miniaturization, the injected impurities are becoming more and more dense. When RTA is used for activation of impurities, on the both surfaces of the wafer, outward diffusion of diffusing substances occurs, and they attach to the inner walls of the chamber, to parts mounted inside the chamber, and further, to the sensing portion of the temperature sensor, to the measuring terminal portion thereof, and the like.

In view of this, the chamber is opened and cleaned manually. However, this method eventually causes a reduction in time of operation of the apparatus. In addition, the period of time of regular processing between cleaning processings is affected by cloud that occurs with time.

In order to solve the problems, a lamp heating apparatus as shown in FIG. 3 is proposed (see, for example, Japanese Patent Application Publication No. 2003-77851).

The lamp heating apparatus has chamber 30 that has transparent window 15 and houses substrate 1 to be annealed, and heating lamps 5 for heating substrate 1 by the radiant heat of the lamps through transparent window 15. The lamp heating apparatus also has a radiation thermometer (not shown) for optically detecting the temperature of substrate 1 with sensing portions 6 formed of optical fibers and provided in chamber 30. After wafer 1 (e.g., silicon wafer) is carried into chamber 30 by an automatic carry-in/out mechanism (not shown), the inside of chamber 30 is divided by substrate supporting portion 4 and wafer 1, making two closed spaces. This results in a structure in which the front surface (the surface on which a semiconductor device is to be formed) of wafer 1 and the rear surface of wafer 1 have independent spaces. Among the spaces, the space at the side of the front surface of wafer 1 is defined as space A2, and the space at the side of the rear surface of wafer 1 is defined as space B3.

At the side of space A2, a plurality of heating lamps 5 are provided via transparent window 15 for lamp. At the time of annealing, the radiant heat of heating lamps 5 is transmitted to wafer 1 via transparent window 15. At the side of space B3, sensing portions 6 formed of optical fibers and connected to a radiation thermometer (not shown) for optically detecting the temperature of wafer 1 are provided.

In addition, at the side wall portions of chamber 30, gas supplying hole 16 and gas exhausting hole 17 are provided to oppose to each other. To gas supplying hole 16, gas supplying system 7 for supplying helium gas as a process gas into space A2 is connected. To gas exhausting hole 17, on the other hand, gas exhausting system 9 for exhausting the gas in space A2 out of chamber 30 is connected.

Further, at the side of space B3, gas supplying hole 18 and gas exhausting hole 19 are provided. To gas supplying hole 18, gas supplying system 10 for supplying a gas composed of oxygen gas and, as its dilution gas, helium gas into space B3 is connected, and to gas exhausting hole 19, gas exhausting system 11 for exhausting the gas in space B3 out of chamber 30 is connected.

An example of the procedure of RTA processing will be described below. First, wafer 1 is automatically carried into chamber 30 the inside of which is substituted with, for example, an inactive gas such as He gas, or is not substituted, and wafer 1 is provided on substrate supporting portion 4, thereby forming space A2 and space B3.

Next, as a process gas, helium gas is supplied into chamber 30 to form a process atmosphere therein. The gas in space B3 is exhausted at a predetermined flow rate. It is noted that since space B3 is, as described above, kept in a substantially closed state because of the weight of wafer 1, there is almost no leakage of He gas from space B3, which is the rear side, to space A2, which is the front side. Space B3 is made to have negative pressure in comparison with space A2.

Then, each of heating lamps 5 is turned on to increase the temperature of wafer 1 from room temperature (25° C.) at a temperature gradient of, for example, 100-150° C./sec (substrate heating step). Meanwhile, by the temperature sensor with a plurality of sensing portions 6, the rearside temperature of wafer 1 is measured in a non-contact manner and on an elapsed time basis, and by a control device (not shown), to make the in-plane temperature of wafer 1 uniform, the heat output of each of heating lamps 5 is adjusted or control between turning-on and turning-off of each of heating lamps 5 is carried out.

Such heating is carried out for a few seconds to ten and a few seconds, and at the time when wafer 1 reaches a predetermined temperature, which is, for example, 1000° C., each of heating lamps 5 is turned off, or adjusted to have a heat output of after-heat nature. Subsequently, in chamber 30, He gas is supplied into space B3 as well as into A2 to cool wafer 1 on the front surface and rear surface thereof. This substrate cooling step is continued until the temperature of wafer 1 becomes a predetermined carrying-out temperature, which is, for example, 750° C. In this case, the rate of temperature-falling is preferably such that the temperature gradient is 50-90° C./sec.

Subsequently, oxygen gas (O₂) is added in and mixed with the helium gas, and this mixture is supplied into space B3. On this occasion, the oxygen gas and helium gas are mixed such that the density of the oxygen gas of the mixture gas in the control device is 500 ppm or more, preferably 500-1000 ppm, more preferably 650-800 ppm. The mixture gas supplied in space B3 is imparted heat energy by radiation from wafer 1 or by heat conduction from the He gas, which is a dilution gas, and in the vicinity of the rear surface of wafer 1, an active species is generated. The active species oxidizes silicon monoxide (SiO) that is a natural oxide film formed on the rear surface of wafer 1, and thus inhibits the sublimation of SiO, thereby realizing reformation into stable SiO₂. In addition, when there is a portion on the rear surface in which Si is exposed microscopically, this is also oxidized to become SiO₂. Thus, on the entire rear surface of wafer 1, a SiO₂ film that efficiently prevents the outward diffusion 13 of sublimation substances and dopants such as phosphorus that are injected in wafer 1 is formed. As a result, the surfaces of sensing portions 6 at the rear surface of wafer 1 are prevented from being cloudy.

However, although the above-described method is effective for inhibiting the occurrence of sublimation substances on the rear surface of wafer 1, transparent window 15 at the front side of wafer is not taken into consideration. In addition, although the oxidization processing inhibits the outward diffusion 13 of diffusing substances, they cannot be entirely prevented, and thus there is still cloud on transparent window 15 and the surfaces of sensing portions 6, creating the need for periodic manual cleaning. In addition, it is not desirable to introduce an oxidizing gas that can be involved in processing for the purpose of cleaning when wafer 1 is in a state of being provided in chamber 30, in that in terms of control of process where miniaturization is being promoted, even if the oxidizing gas is in a minute amount, there is a possibility of being affected by turning-around of the oxidizing gas.

### SUMMARY OF THE INVENTION

In order to solve the above and other problems, it is an object of the present invention to provide a lamp heating apparatus that removes cloud on the transparent window and stabilizes the measurement system and the like associated with temperature control of the substrate.

It is another object of the present invention to provide a lamp heating apparatus that has good temperature uniformity and reproductivity of heat processing conditions.

It is another object of the present invention to provide a lamp heating apparatus with which process stability improves.

It is another object of the present invention to provide a lamp heating apparatus that keeps the inside of the chamber clean and inhibits the occurrence of foreign substances such as particles.

It is another object of the present invention to provide a method of producing a semiconductor device by using the lamp heating apparatus.

A lamp heating apparatus according to the present invention comprises: a chamber comprising a transparent window and housing a substrate; a heating lamp for heating the substrate by radiant heat of the heating lamp through the transparent window; a radiation thermometer for optically detecting a temperature of the substrate, the radiation thermometer comprising a sensing portion provided in the chamber; a radical supplying means for generating a radical outside the chamber and supplying the radical into the chamber; and a means for determining a time for cleaning an inside of the chamber from a cloudy state of the transparent window and a surface of the sensing portion; the lamp heating apparatus wherein a series of operations comprising heat annealing of the substrate and cleaning of the inside of the chamber is made possible.

With the lamp heating apparatus according to this invention, since heat annealing of the substrate and cleaning of the inside of the chamber is made one series of operations, the measurement system associated with temperature control of the substrate is stabilized. In addition, since the radical is generated outside the chamber, there is no physical damage resulting from plasma irradiation, and the transparent window and the surface of the sensing portion do not become rough.

In a preferred embodiment of this invention, the radical is one selected from the group consisting of hydrogen, oxygen, and a fluorocarbon compound.

In a preferred embodiment of this invention, the lamp heating apparatus further comprises a detecting means for detecting the cloudy state of the transparent window and the surface of the sensing portion. With this structure, the time for cleaning the inside of the chamber is determined.

The chamber may comprise two closed spaces with the substrate sandwiched therebetween, when the substrate is housed in the chamber.

In this case, the detecting means comprises: a light quantity sensor provided in the sensing portion; and a light emitting means for emitting light to the surface of the sensing portion through the transparent window, the light emitting means being provided outside the chamber and opposed to the sensing portion.

With this structure, when, after the substrate is carried out of the chamber, there is no interference between the light quantity sensor and the light emitting means, by measuring the quantity of the light that is emitted from the light emitting means and reaches the inside of the sensing portion, the cloudy state of the transparent window and the surface of the sensing portion is detected.

A method for producing a semiconductor device according to another aspect of the present invention is such that in the production process of a semiconductor device with the use of the above lamp heating apparatus, the transparent window and the surface of the sensing portion are cleaned with the use of the radical, during a period between one or a plurality of times of annealing.

With this method, the measurement system associated with temperature control of the substrate is stabilized, and temperature uniformity and reproductivity of heat processing conditions are made better, leading to a state in which process stability is improved. In addition, the inside of the chamber is kept clean and the occurrence of foreign substances such as particles is inhibited.

A method for producing a semiconductor device according to another aspect of the present invention is such that in the production process of a semiconductor device with the use of the above lamp heating apparatus, the cloudy state of the transparent window and the surface of the sensing portion is detected, and every time the cloudy state exceeds a predetermined cloudy state, the transparent window and the surface of the sensing portion are cleaned with the use of the radical.

A method for producing a semiconductor device according to another aspect of the present invention is such that in the production process of a semiconductor device with the use of the above lamp heating apparatus, one time of annealing is divided into a plurality of times of annealing with a cleaning step with the use of the radical interposed between the plurality of times of annealing. With this method, the thermal history (thermal budget) of the substrate is reduced.

A method for producing a semiconductor device according to another aspect of the present invention comprises the steps of: housing a substrate into a chamber comprising a transparent window; annealing the substrate by radiant heat of a heating lamp through the transparent window while detecting by a sensing portion a temperature of the substrate; and cleaning the transparent window and a surface of the sensing portion with the use of a radical, during a period between one or a plurality of times of annealing.

A method for producing a semiconductor device according to another aspect of the present invention comprises the steps of: housing a substrate into a chamber comprising a transparent window; annealing the substrate by radiant heat of a heating lamp through the transparent window while detecting by a sensing portion a temperature of the substrate; and while detecting a cloudy state of the transparent window and a surface of the sensing portion, and every time the cloudy state exceeds a predetermined cloudy state, cleaning the transparent window and the surface of the sensing portion with the use of a radical.

A method for producing a semiconductor device according to another aspect of the present invention comprises the steps of: housing a substrate into a chamber comprising a transparent window; annealing the substrate by radiant heat of a heating lamp through the transparent window while detecting by a sensing portion a temperature of the substrate; and cleaning the transparent window and a surface of the sensing portion with the use of a radical, the method wherein one time of annealing is divided into a plurality of times of annealing with a cleaning step interposed between the plurality of times of annealing.

The checking of the cloudy state of the transparent window and a surface of the sensing portion preferably comprises: providing a light quantity sensor in the sensing portion; emitting light to the surface of the sensing portion from an outside of the chamber through the transparent window; and obtaining an quantity of light reaching an inside of the sending portion.

According to the present invention, since, in an RTA processing apparatus, between substrate processings, a radical of oxygen, hydrogen, a fluorocarbon compound, or the like is supplied from the outside of the chamber into the inside thereof, contaminated substances contaminated by dopants such as phosphorus, arsenic, and boron, which occur upon heat processing, are cleaned away in-situ. In addition, since no plasma occurs in the inside of the chamber, there is no physical damage resulting from plasma irradiation, and the transparent window and the surface of the sensing portion do not become rough. As a result, the measurement system associated with temperature control of the substrate is stabilized, and temperature uniformity and reproductivity of heat processing conditions are made better, leading to improved process stability. Further, there are such advantageous effects that the inside of the chamber is kept clean and the occurrence of foreign substances such as particles is inhibited.

### BRIEF DESCRIPTION OF THE DRAWINGS

FIG. 1 is a schematic cross-section of a heat processing apparatus according to the present invention.

FIG. 2 is a flow chart of the processing of the heat processing apparatus shown in FIG. 1.

FIG. 3 is a schematic cross-section of a conventional heat processing apparatus.

### DESCRIPTION OF THE PREFERRED EMBODIMENTS

The object of providing a lamp heating apparatus that stabilizes the measurement system associated with temperature control of the substrate has been realized by such a structure that the inside of the chamber is cleaned with the use of a radical when the cloudy state of the transparent window and the surface of the sensing portion exceeds a predetermined cloudy state, and that a series of operations comprising heat annealing of the substrate and cleaning of the inside of the chamber is made possible. An embodiment of the present invention will be described below referring to the drawings.

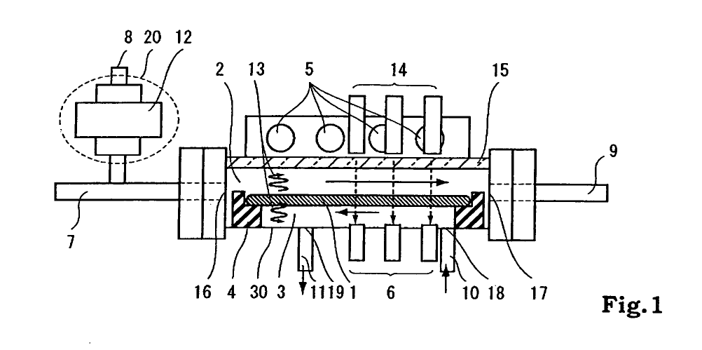

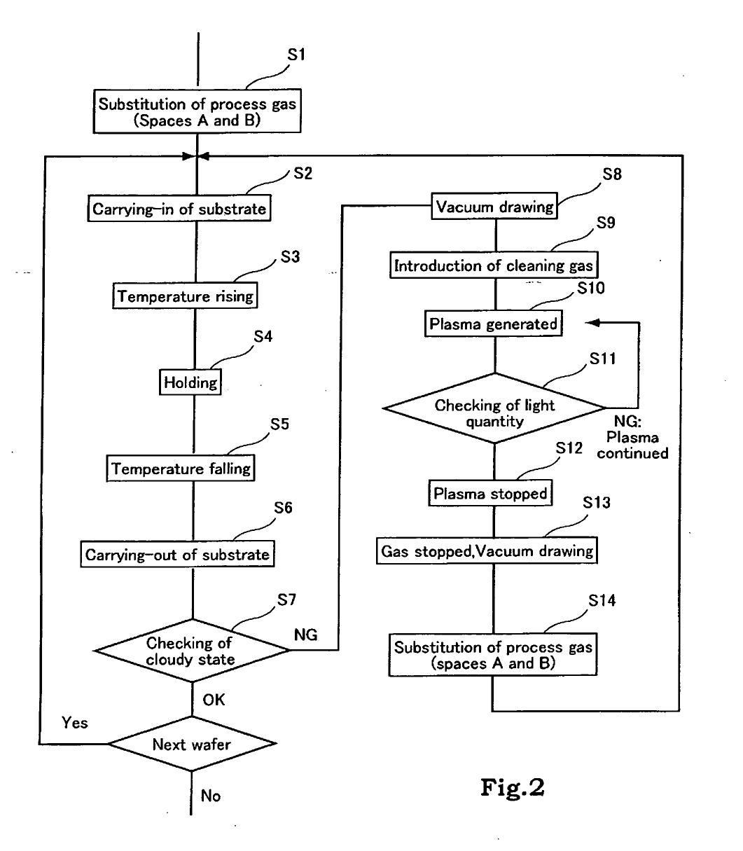

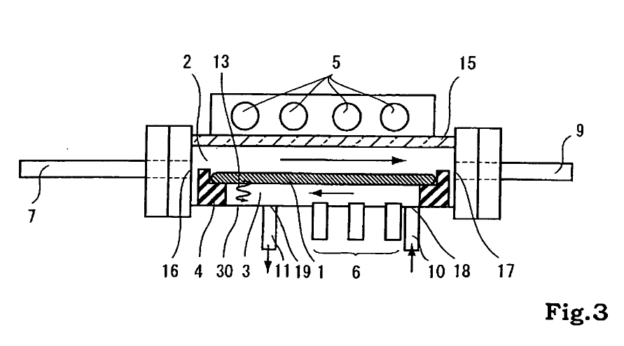

FIG. 1 is a schematic cross-section of a heat processing apparatus according to the present invention. FIG. 2 is a flow chart showing a method of producing a semiconductor device with the use of the lamp heating apparatus. In FIGS. 1 and 3, like parts in the figures are denoted by like reference numbers.

A lamp heating apparatus according to this embodiment has chamber 30 that has transparent window 15 and houses substrate 1 to be annealed, and heating lamps 5 for heating substrate 1 by the radiant heat of the lamps through transparent window 15. The lamp heating apparatus also has a radiation thermometer (not shown) for optically detecting the temperature of substrate 1 with sensing portions 6 formed of optical fibers and provided in chamber 30.

After wafer 1 is carried into chamber 30 by an automatic carry-in/out mechanism (not shown), the inside of chamber 30 is divided by substrate supporting portion 4 and wafer 1, making two closed spaces. This results in a structure in which the front surface (the surface on which a semiconductor device is to be formed) of wafer 1 and the rear surface of wafer 1 have independent spaces. The space at the side of the front surface of wafer 1 is defined as space A2, and the space at the side of the rear surface of wafer 1 is defined as space B3. While the structure here is divided by wafer 1, a structure not in a state of division is within the scope of the present invention.

At the side of space A2, a plurality of heating lamps 5 are provided via transparent window 15 for lamp. At the time of annealing, the radiant heat of heating lamps 5 is transmitted to wafer 1 via transparent window 15. At the side of space B3, sensing portions 6 formed of optical fibers and connected to a radiation thermometer (not shown) for optically detecting the temperature of wafer 1 and to a light quantity sensor (not shown) are provided. The radiation thermometer and light quantity sensor can be switched between themselves by a light switch (not shown).

Optical fibers 14 connected to a LED light source (not shown) are provided symmetrically with respect to sensing portions 6 over chamber 30. When wafer 1 is automatically carried out of the chamber and there is no interference between optical fibers 14 and sensing portions 6, the light emitted from the LED light source passes through optical fibers 14 and transparent window 15, and then through the inside of chamber 30 along the light passages indicated by the dotted arrows, and finally reaches the insides of sensing portions 6 formed of optical fibers from the surfaces of sensing portions 6. Because of this structure, when wafer 1 is not mounted, by measuring the amount of the light that has reached the insides of sensing portions 6, the cloud on the surfaces of the fibers at both sides and on transparent window 15 can be detected.

In addition, at the side wall portions of chamber 30, gas supplying hole 16 and gas exhausting hole 17 are provided to oppose to each other. To gas supplying hole 16, gas supplying system 7 for supplying N₂ gas as a process gas and gas supplying system 8 for supplying a hydrogen radical as a cleaning gas into space A2 are connected.

Radical generating portion 20 is of a remote plasma system distanced from chamber 30. By making the inside of the pipe a depressurized state (e.g., 200 Pa) and by externally applying a high frequency (e.g., 2.45 GHz) supplied from wave-guide 12, the hydrogen gas inside the pipe is turned into plasma. Thus, a hydrogen radical is generated. To gas exhausting hole 17, on the other hand, gas exhausting system 9 for exhausting the gas in space A2 out of chamber 30 is connected.

While in this embodiment, as an example of a gas to be supplied to radical generating portion 20, single hydrogen gas is used, other gases than the single hydrogen gas can be selected including oxygen, fluorocarbon, or a mixture gas of them, or a gas in which any of the foregoing is diluted by an inactive gas such as helium. In addition, as a process gas, other gases than N₂ can be used including an inactive gas such as helium, and oxygen, and an oxygen-based gas containing oxygen (e.g., N₂O), or a gas in which any of the foregoing is diluted by an inactive gas such as helium.

Further, at the side of space B3, gas supplying hole 18 and gas exhausting hole 19 are provided. To gas supplying hole 18, gas supplying system 10 for supplying N₂ gas into space B3 is connected, and to gas exhausting hole 19, gas exhausting system 11 for exhausting the gas in space B3 out of chamber 30 is connected. Also in this gas system, as in the process gas, other gases than N₂ can be used including an inactive gas such as helium, an oxygen-based gas containing oxygen (e.g., N₂O), or a gas in which any of the foregoing is diluted by an inactive gas such as helium.

Next, an example of the procedure of RTA processing of a semiconductor device will be described using the flow chart shown in FIG. 2.

Referring to FIGS. 1 and 2, in step S1, the inside of chamber 30 is substituted with nitrogen gas (process gas). In step S2, wafer 1 (Si wafer) is automatically carried into chamber 30 (carry-in of substrate), the inside of which is substituted with nitrogen gas, and wafer 1 is provided on substrate supporting portion 4, thereby forming space A2 and space B3.

Next, supply and exhaustion of gas with respect to space B3 are carried out at a predetermined flow rate. To prevent wafer 1 from being raised, the flow rate and the amount of exhaustion are controlled to make space B3 have negative pressure in comparison with space A2. Since in the annealing at the time of phosphorus doping, the outward diffusion 13 of the phosphorus usually occurs, diffusion and activation are carried out while proceeding oxidization with the use of an oxidizing agent such as oxygen gas. It should be noted, however, that since the apparatus according to this embodiment has a cleaning mechanism, even if outward diffusion 13 cannot be eliminated because process restrictions (for example, the case of simultaneously activating a boron dopant and a phosphorus dopant that are injected without a screen oxide film) do not permit oxidization, the dirt in each processing are removed thereafter. Further, one time of annealing can be divided into a plurality of times of annealing by interposing a plurality of times of cleaning in one time of annealing, so as to obtain a desired thermal budget.

Then, in step S3, each of heating lamps 5 is turned on to increase the temperature of wafer 1 from room temperature (25° C.)-idle temperature (100° C.) to a uniformity stabilized temperature (400° C.). Then, temperature rising is carried out such that the temperature is increased rapidly at a temperature gradient of, for example, 50-300° C./sec (temperature rising). Meanwhile, by a plurality of sensing portions 6, the rearside temperature of wafer 1 is measured in a non-contact manner and on an elapsed time basis, and by a control device (not shown), to make the in-plane temperature of wafer 1 uniform, the heat outputs of heating lamps 5 are adjusted or the control between turning-on and turning-off of each of heating lamps 5 is carried out. Such heating is carried out for a few seconds to ten and a few seconds (temperature rising), and in step S4, at the time when wafer 1 reaches a predetermined temperature, which is, for example, 1000° C., the temperature is held uniform for a predetermined period of time (holding). It is noted that as in spike annealing the period of time for holding can be made zero.

In step S5, the lamp group is turned off, or adjusted to have a heat output of after-heat nature (temperature-falling). Subsequently, in chamber 30, He gas is supplied into space B3 as well as A2 to cool wafer 1 on the front surface and rear surface thereof. This substrate cooling step is continued until the temperature of wafer 1 becomes a predetermined carrying-out temperature, which is, for example, 750° C. In this case, the rate of temperature-failing is preferably such that the temperature gradient is 50-300° C./sec.

Next, in step S6, wafer 1 is automatically carried out of chamber 30 (carrying-out of substrate). This step eliminates the interference between the light source and the sensors, enabling the checking of light quantity. In this system, in step S7, when a predetermined light quantity cannot be obtained because of occurrence of cloud, a threshold value in the light quantity sensor can be set to cause automatic switching to the cleaning sequence (checking of cloudy state).

When the threshold value is exceeded, in step S8, the supply of the process gas into chamber 30 is stopped, and the inside of chamber 30 is subject to vacuum drawing (vacuum drawing). After completion of vacuum drawing, in step S9, hydrogen gas is supplied into the pipe in which a remote plasma is generated introduction of cleaning gas). In step S10, after the insides of the pipe and chamber 30 are kept at, for example, 200 Pa, a high frequency of 2.45 GHz is applied, thus generating a plasma. Thus, a hydrogen radical is generated. By supplying the hydrogen radical into chamber 30, the phosphorus, boron, and arsenic attached on the inside of chamber 30 react with the hydrogen and are exhausted as hydrogenated gases.

On this occasion, in step S11, the light quantity is continuously checked, and when the light quantity reaches a predetermined level, in step S12, the application of the high frequency is stopped (plasma stopped). Subsequently, in step S13, the supply of hydrogen is stopped (gas stopped), and after carrying out vacuum drawing (vacuum drawing), in step S14, the chamber atmosphere is substituted with nitrogen gas, which is the process gas (process gas substitution), and then back in step S2, next wafer 1 is carried in and processed.

While this embodiment has shown a process flow in which the processing of one wafer is completed in one time of processing, the heat processing can be divided into a plurality of times of heat processing, which is realized by acquiring data about cloud in advance, in which case an equivalent thermal history is obtained.

While in this embodiment silicon wafer is taken as an example of the wafer, the present invention is not limited to this.

The embodiment herein described is to be considered in all respects as illustrative and not restrictive. The scope of the invention should be determined not by the Embodiments illustrated, but by the appended claims, and all changes which come within the meaning and range of equivalency of the appended claims are therefore intended to be embraced therein.

As has been described hereinbefore, according to the present invention, since the thermal history of the substrate is reduced, thinning and miniaturization of the device is realized.

1. A lamp heating apparatus comprising:
a chamber comprising a transparent window and housing a substrate;
a heating lamp for heating the substrate by radiant heat of the heating lamp through the transparent window;
a radiation thermometer for optically detecting a temperature of the substrate, the radiation thermometer comprising a sensing portion provided in the chamber;
a radical supplying means for generating a radical outside the chamber and supplying the radical into the chamber; and
a means for determining a time for cleaning an inside of the chamber from a cloudy state of the transparent window and a surface of the sensing portion;
the lamp heating apparatus wherein
a series of operations comprising heat annealing of the substrate and cleaning of the inside of the chamber is made possible.

2. The lamp heating apparatus according to claim 1, wherein the radical is one selected from the group consisting of hydrogen, oxygen, and a fluorocarbon compound.

3. The lamp heating apparatus according to claim 1, further comprising a detecting means for detecting the cloudy state of the transparent window and the surface of the sensing portion.

4. The lamp heating apparatus according to claim 1, wherein the chamber comprises two closed spaces with the substrate sandwiched therebetween, when the substrate is housed in the chamber.

5. The lamp heating apparatus according to claim 3, wherein the detecting means comprises:
a light quantity sensor provided in the sensing portion; and
a light emitting means for emitting light to the surface of the sensing portion through the transparent window, the light emitting means being provided outside the chamber and opposed to the sensing portion.

6. A method for producing a semiconductor device, wherein in a production process of a semiconductor device with the use of the lamp heating apparatus according to claim 1, the transparent window and the surface of the sensing portion are cleaned with the use of the radical, during a period between one or a plurality of times of annealing.

7. A method for producing a semiconductor device, wherein in a production process of a semiconductor device with the use of the lamp heating apparatus according to claim 1, the cloudy state of the transparent window and the surface of the sensing portion is detected, and every time the cloudy state exceeds a predetermined cloudy state, the transparent window and the surface of the sensing portion are cleaned with the use of the radical.

8. A method for producing a semiconductor device, wherein in a production process of a semiconductor device with the use of the lamp heating apparatus according to claim 1, one time of annealing is divided into a plurality of times of annealing with a cleaning step with the use of the radical interposed between the plurality of times of annealing.

9. A method for producing a semiconductor device, the method comprising the steps of:
housing a substrate into a chamber comprising a transparent window;
annealing the substrate by radiant heat of a heating lamp through the transparent window while detecting by a sensing portion a temperature of the substrate; and
cleaning the transparent window and a surface of the sensing portion with the use of a radical, during a period between one or a plurality of times of annealing.

10. A method for producing a semiconductor device, the method comprising the steps of
housing a substrate into a chamber comprising a transparent window;
annealing the substrate by radiant heat of a heating lamp through the transparent window while detecting by a sensing portion a temperature of the substrate; and
while detecting a cloudy state of the transparent window and a surface of the sensing portion, and every time the cloudy state exceeds a predetermined cloudy state, cleaning the transparent window and the surface of the sensing portion with the use of a radical.

11. A method for producing a semiconductor device, the method comprising the steps of:
housing a substrate into a chamber comprising a transparent window;
annealing the substrate by radiant heat of a heating lamp through the transparent window while detecting by a sensing portion a temperature of the substrate; and
cleaning the transparent window and a surface of the sensing portion with the use of a radical, the method wherein
one time of annealing is divided into a plurality of times of annealing with a cleaning step interposed between the plurality of times of annealing.

12. The method for producing a semiconductor device according to claim 7, wherein the checking of the cloudy state of the transparent window and a surface of the sensing portion comprises:
providing a light quantity sensor in the sensing portion;
emitting light to the surface of the sensing portion from an outside of the chamber through the transparent window; and
obtaining an quantity of light reaching an inside of the sending portion.

13. The method for producing a semiconductor device according to claim 6, wherein the radical is one selected from the group consisting of hydrogen, oxygen, and a fluorocarbon compound.
